(19) United States
(12) Patent Application Publication
(10) Pub. No.: US 2020/0263295 A1
(43) Pub. Date: Aug. 20, 2020

(54) FILM FORMING METHOD, METHOD FOR CLEANING PROCESSING CHAMBER FOR FILM FORMATION, AND FILM FORMING APPARATUS

(71) Applicant: TOKYO ELECTRON LIMITED, Tokyo (JP)

(72) Inventors: Takahiro MIYAHARA, Albany, NY (US); Susumu YAMAUCHI, Yamanashi (JP)

(21) Appl. No.: 16/786,808

(22) Filed: Feb. 10, 2020

(30) Foreign Application Priority Data
Feb. 15, 2019 (JP) 2019-025362

(51) Int. Cl. C23C 16/32; H01L 21/02; C23C 16/44; H01J 37/32; C23C 16/52; C23C 16/455

(52) U.S. Cl. CPC C23C 16/325; H01L 21/0228; C23C 16/4405; H01L 21/02274; H01L 21/02167; H01J 2237/3321; H01J 37/32449; C23C 16/52; C23C 16/4412; C23C 16/45536; C23C 16/45544; H01J 37/32834

(57) ABSTRACT

A film forming method is provided. In the film forming method, a gas of a carbon precursor containing an organic compound having an unsaturated carbon bond is supplied to a substrate, and a gas of a silicon precursor containing a silicon compound is supplied to the substrate. Further, a carbon-silicon containing film is formed on the substrate by thermally reacting the carbon precursor with the silicon precursor at a temperature lower than 800° C.

### CROSS-REFERENCE TO RELATED APPLICATIONS

This application claims priority to Japanese Patent Application No. 2019-025362, filed on Feb. 15, 2019, the entire contents of which are incorporated herein by reference.

### TECHNICAL FIELD

The present disclosure relates to a film forming method, a method for cleaning a processing chamber for film formation, and a film forming apparatus.

### BACKGROUND

A multi-gate fin-field effect transistor (Fin-FET) that is a semiconductor device has a high degree of integration, and a plurality of films may be exposed to an opening formed in a hard mask. Therefore, there is a demand for a hard mask material capable of etching a desired film among the films exposed to a fine opening with high selectivity. It is preferred if the material can be used as an insulating film or a low-dielectric constant film (low-k film) without being selectively removed after it is used as the hard mask. Therefore, a technique for forming a carbon-silicon containing film (hereinafter referred to as “SiC film”) as a material that satisfies such a demand has been developed.

Japanese Patent Application Publication No. 2006-147866 discloses a technique for forming a SiC film by chemical vapor deposition (CVD) at a high temperature of 1000° C. or higher using a gas containing carbon such as propane or the like and an organic silane such as monosilane, disilane, or the like. Japanese Patent Application Publication No. 2007-88017 discloses a technique using an organic silane having a carbon carbon triple bond such as bis(trimethylsilyl)acetylene or the like as a source gas. In this technique, a SiCH film or a SiCNH film is formed by plasma CVD on a substrate heated to a temperature of 200° C. to 400° C.

In view of the above, the present disclosure provides a technique for forming a carbon-silicon containing film at a temperature lower than 800° C.

### SUMMARY

In accordance with an aspect of the present disclosure, there is provided a film forming method including: supplying a gas of a carbon precursor containing an organic compound having an unsaturated carbon bond to a substrate; supplying a gas of a silicon precursor containing a silicon compound to the substrate; and forming a carbon-silicon containing film on the substrate by thermally reacting the carbon precursor with the silicon precursor at a temperature lower than 800° C.

### BRIEF DESCRIPTION OF THE DRAWINGS

The objects and features of the present disclosure will become apparent from the following description of embodiments, given in conjunction with the accompanying drawings, in which:

FIG. 1 shows a chemical reaction formula explaining an example of a film forming method according to an embodiment of the present disclosure;

FIG. 2 shows an example of a reaction model of the film forming method;

FIG. 3 shows another example of the reaction model of the film forming method;

FIG. 4 is a vertical cross-sectional side view showing an example of a film forming apparatus according to an embodiment of the present disclosure;

FIG. 5 is a time chart showing an example of the film forming method;

FIGS. 6A to 6D show an example of a method for cleaning a processing chamber for film formation according to an embodiment of the present disclosure;

FIG. 7 shows a chemical reaction formula explaining another example of the film forming method;

FIG. 8 shows an example of a carbon precursor;

FIG. 9 shows an example of a silicon precursor;

FIG. 10 is a vertical cross-sectional side view showing another example of the film forming apparatus;

FIG. 11 is a horizontal cross-sectional planar view showing still another example of the film forming apparatus;

FIG. 12 is a time chart showing another example of the film forming method;

FIGS. 13 and 14 are characteristic diagrams showing evaluation results of the film forming method;

FIGS. 15 and 16 explain bonding states of carbon and silicon;

FIG. 17 is a characteristic diagram showing an evaluation result of the film forming method; and

FIG. 18 is a characteristic diagram showing an evaluation result of a cleaning method.

### DETAILED DESCRIPTION

In a film forming method according to an embodiment of the present disclosure, a SiC film is formed on a substrate by supplying a carbon precursor gas and a silicon precursor gas to the substrate and thermally reacting the two precursor gases at a temperature lower than 800° C. The substrate is, e.g., a semiconductor wafer (hereinafter, referred to as “wafer”). For the carbon precursor, a precursor containing an organic compound having an unsaturated carbon bond is used. For example, the organic compound may be a compound having a nucleophilic side chain such as a halogen atom or the like. For the silicon precursor, a precursor containing a silicon compound is used. The silicon compound generates, e.g., radicals having unpaired electrons in silicon (Si) atoms at a thermal reaction temperature.

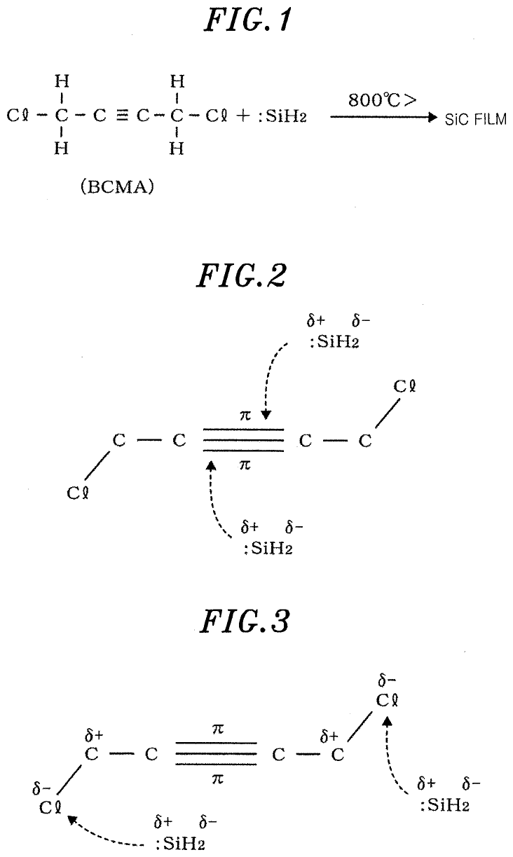

FIG. 1 shows an example in which a carbon precursor such as bis(chloromethyl)acetylene (BCMA), having a triple bond that is an unsaturated carbon bond, and a silicon precursor such as disilane (Si₂H₆) thermally react at a temperature lower than 800° C. It is presumed that disilane is heated to about 400° C. and thermally decomposed to generate SiH₂ radicals having unpaired electrons in Si atoms, and the generated SiH₂ radicals react with BCMA to form a SiC film.

Conventionally, it is considered that the SiC film is formed by reacting a carbon-containing gas and an organic silane at a high temperature of 1000° C. or higher, or by generating plasma of these gases and reacting them at a temperature lower than 1000° C.

On the other hand, as described above, in the film forming method according to the embodiment of the present disclosure, the SiC film is formed by thermal reaction at a temperature lower than 800° C., preferably 500° C. or lower, without using plasma. The mechanism for forming a SiC film at a low temperature will be described using a reaction model 1 shown in FIG. 2 and a reaction model 2 shown in FIG. 3.

As described above, disilane is heated to about 400° C. and thermally decomposed to generate SiH2 radicals having unpaired electrons in Si atoms. The SiH2 radicals are polarized to σ+ and σ−. In the reaction model 1, it is presumed that the positive polarization site (σ+) serves as an electrophile that attacks a π bond of the unsaturated bond of BCMA having a large number of electrons to decompose BCMA, and a SiC bond is formed by a reaction between C of the triple bond and Si of the SiH₂ radicals. The π bond of the triple bond of BCMA has a weaker bonding force than that of the σ bond. Thus, if the SiH₂ radicals attack the π bond, the thermal reaction proceeds sufficiently even at a temperature of 400° C. or lower, thereby generating the SiC bond.

In the reaction model 2 shown in FIG. 3, BCMA has a nucleophilic property in which polarization occurs due to a halogen group (Cl group) and the positive polarization site (σ+) of the SiH₂ radicals attacks the negative polarization site (σ−). Therefore, it is presumed that a SiC bond is formed by a reaction between the SiH₂ radicals and C at the molecular end that is bonded to Cl. From the above, it is clear that a SiC film can be formed at a temperature lower than 800° C. without using plasma by selecting a carbon precursor and a silicon precursor that allow a reaction for forming a SiC bond to proceed at a temperature lower than 800° C.

The selected carbon precursor has an unsaturated carbon bond or a nucleophilic side chain, and the selected silicon precursor becomes an active species at a temperature lower than, e.g., 800° C. In the case of using BCMA as the carbon precursor and disilane as the silicon precursor, thermal reaction occurs at a temperature of 350° C. to 400° C. In this case, it is presumed that both of the reactions in the reaction models 1 and 2 proceed to form a SiC film. The reaction models 1 and 2 explain the reason that the SiC film can be formed at a low temperature, which was conventionally difficult to achieve. However, the reaction of the embodiment is not limited thereto. As long as the SiC film can be formed at a temperature lower than 800° C. without using plasma, the SiC film may be formed by a different reaction.

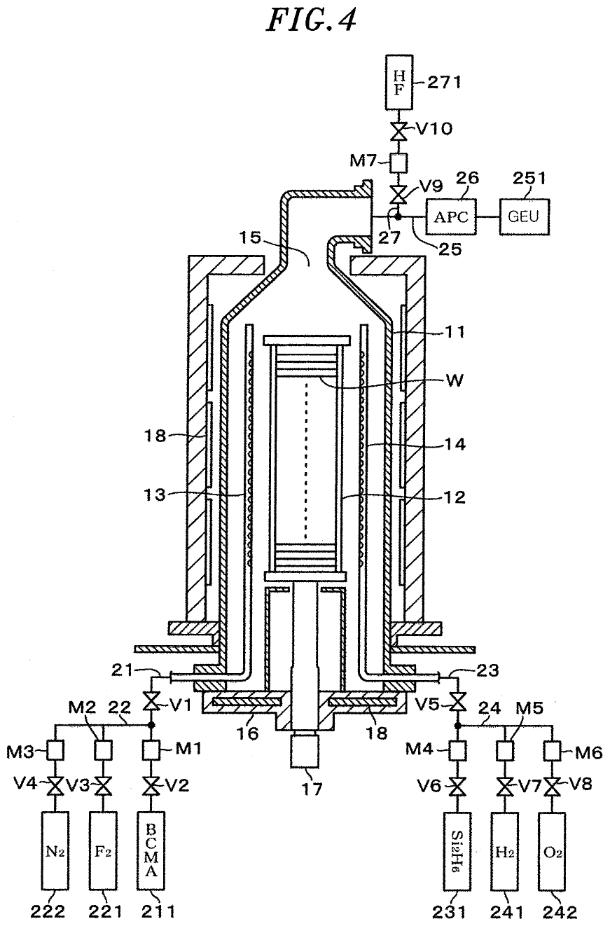

Next, a batch-type vertical heat treatment apparatus that is an example of the film forming apparatus according to the embodiment of the present disclosure will be briefly described with reference to FIG. 4. In this apparatus, a reaction tube 11 that is a processing chamber made of quartz glass is provided. A wafer boat 12 having shelves to be stacked with a plurality of wafers W is airtightly accommodated in the reaction tube 11 from a lower side. The wafer boat 12 serves as a mounting table mounting the wafer W. In the reaction tube 11, two gas injectors 13 and 14 are disposed along a longitudinal direction of the reaction tube 11 to be positioned opposite to each other with the wafer boat 12 interposed therebetween.

The gas injector 13 is connected to a supply source 211 for supplying a carbon precursor, e.g., BCMA, through, e.g., a gas supply line 21. Further, the gas injector 13 is connected to a supply source 221 for supplying a cleaning gas, e.g., fluorine (F₂) gas, and a supply source 222 for supplying a purge gas, e.g., nitrogen (N₂) gas, through a branch line 22 branched from the gas supply line 21, for example. In this example, the carbon precursor supply unit for supplying the carbon precursor gas to the reaction tube 11 includes the gas supply line 21 and the BCMA supply source 211.

The gas injector 14 is connected to a supply source 231 for supplying a silicon precursor, e.g., disilane, through a gas supply line 23, for example. Further, the gas injector 14 is connected to a hydrogen (H₂) gas supply source 241 and an oxygen (O₂) gas supply source 242 through a branch line 24 branched from the gas supply line 23, for example. In this example, the silicon precursor supply unit for supplying the silicon precursor gas to the reaction tube 11 includes the gas supply line 23 and the disilane supply source 231.

The silicon precursor supply unit also serves as a silicon film source supply unit for supplying an amorphous silicon source gas to the reaction tube 11. In this example, the amorphous silicon source gas is disilane. In this example, for the sake of convenience of illustration, N₂ gas and F₂ gas join to flow through the gas supply line for the carbon precursor, and O₂ gas and H₂ gas join to flow through the gas supply line for the silicon precursor. A dedicated supply nozzle for these gases (N₂ gas, F₂ gas, O₂ gas and H₂ gas) may be separately inserted into the reaction tube 11. The O₂ gas and the H₂ gas correspond to a first cleaning gas. However, the first cleaning gas does not necessarily include H₂ gas, as will be described later. Therefore, in this example, a first cleaning gas supply unit for supplying the first cleaning gas to the reaction tube 11 includes at least the O₂ gas supply source 242 and a supply line for supplying O₂ gas to the reaction tube 11.

A gas exhaust port 15 is formed at an upper end portion of the reaction tube 11 and is connected to a gas exhaust unit (GEU) 251 through a vacuum exhaust line 25 that is made of a metal and provided with a pressure control valve (APC) 26. The pressure control valve 26 is capable of opening and closing the vacuum exhaust line 25. By adjusting an opening degree of the pressure control valve 26 to increase and decrease a conductance of the vacuum exhaust line 25, a pressure in the reaction tube 11 can be controlled. An adaptive pressure control (APC) valve such as a butterfly valve or the like is used as the pressure control valve 26. A supply source 261 for supplying a second cleaning gas, e.g., hydrogen fluoride (HF) gas, is connected to the vacuum exhaust line 25 through a branch line 27 formed near an upstream side of the pressure control valve 26. In this example, a second cleaning gas supply unit for supplying the second cleaning gas to the vacuum exhaust line 25 includes the branch line 27 and a HF gas supply source (HF) 271.

In FIG. 4, reference numerals “V1” to “V10” denote opening/closing valves, and reference numerals “M1” to “M7” denote flow rate controllers. In FIG. 4, a reference numeral “16” denotes a lid for opening and closing an opening formed at a lower end of the reaction tube 11, and a reference numeral “17” denotes a rotation mechanism for rotating the wafer boat 12 about a vertical axis. A heating unit 18 is disposed in the lid 16 around the reaction tube 11 to heat the wafer W mounted in the wafer boat 12 to a temperature lower than 800° C., e.g., a temperature of 350° C. to 400° C.

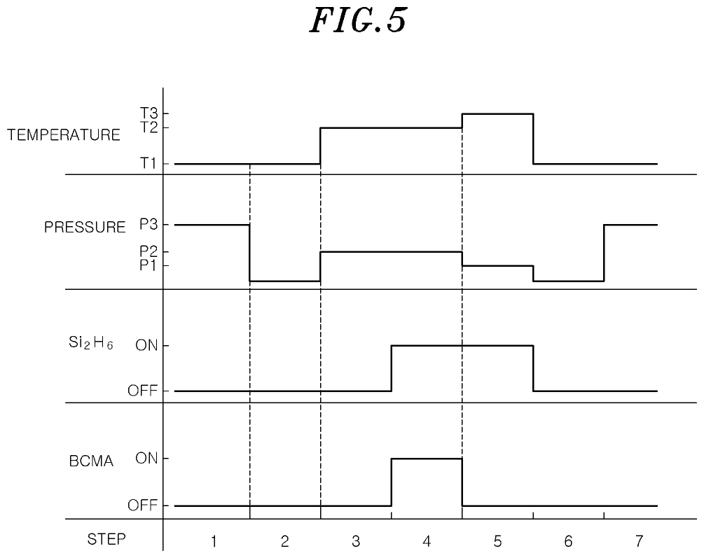

A film forming method performed by this vertical heat treatment apparatus will be described with reference to the time chart of FIG. 5. First, before the film formation is started, an inner wall surface of the reaction tube 11 where the wafer W is not yet loaded is coated with an amorphous silicon film (amorphous Si film). This process is performed by loading the wafer boat 12 without a mounted wafer W into the reaction tube 11, heating the reaction tube 11 to a temperature of, e.g., 400° C. while maintaining a pressure in the reaction tube 11 at, e.g., 133 Pa (1 Torr), and supplying disilane into the reaction tube 11. Accordingly, disilane is thermally decomposed, and an amorphous Si film is formed on the inner wall of the reaction tube 11 and on an outer surface of the wafer boat 12.

Next, in step 1, the wafer boat 12 mounting a plurality of wafers W is loaded into the reaction tube 11; the lid 16 of the reaction tube 11 is closed; and the reaction tube 11 is heated. In step 1, a set pressure P3 in the reaction tube 11 is, e.g., an atmospheric pressure, and a set temperature T1 is, e.g., 350° C. Then, in step 2, the reaction tube 11 is vacuum-evacuated. Thereafter, in step 3, the pressure and the temperature in the reaction tube 11 are controlled and stabilized to a set pressure P2 (e.g., within a range from 399.9 Pa to 533.2 Pa (3 Torr to 4 Torr)) and a set temperature T2 (e.g., 390° C.), respectively, while supplying N₂ gas for the pressure control. Next, in step 4, BCMA gas as the carbon precursor and disilane gas as the silicon precursor are supplied to the wafer W concurrently. In this manner, BCMA and disilane thermally react at a temperature lower than 800° C., e.g., 390° C., to form a SiC film on the wafer W.

Specifically, in step 4, BCMA as the carbon precursor and disilane as the silicon precursor are respectively supplied from the gas injectors 13 and 14 into the reaction tube 11 at predetermined flow rates. Since the reaction tube 11 is heated to 390° C., the reaction between BCMA and SiH₂ radicals generated by thermal decomposition of disilane proceeds in the reaction tube 11 as described above. Accordingly, a SiC film is formed on the surface of each of the wafers W by CVD.

As will be described in the following test examples, in the case of analyzing the chemical bonding state of the formed SiC film by X-ray photoelectron spectroscopy (XPS), a bond between Si and C (Si—C bond) was detected. Further, when the formation of the SiC film was performed with different film formation conditions including film forming temperature, ratio of a supplied flow rate of disilane with respect to a flow rate of BCMA, and the like, it was found that the film forming speed of SiC depends on the temperature or the supplied flow rate of disilane. As described in the above reaction models, in the reaction for forming a SiC film at a low temperature, it is preferable to generate active species (SiH₂ radicals) by thermal decomposition of disilane. Therefore, in order to generate SiH₂ radicals, the thermal reaction preferably occurs at a temperature of 350° C. or higher, and more preferably at a temperature of 380° C. or higher.

As will be described in the following test examples, it was found that the component amount of the SiC film can be adjusted by adjusting the ratio of the flow rate of disilane to the flow rate of BCMA (disilane flow rate/BCMA flow rate). The adjustment of the component amount of the SiC film indicates the change in the number of Si bonded to C contained in the SiC film. The SiC film can have different characteristics depending on uses by adjusting the flow rate ratio of disilane (silicon precursor) to BCMA (carbon precursor). However, as will be described later, if the flow rate of the silicon precursor of the flow rate ratio of Si₂H₆/BCMA exceeds a certain value, the component amount of the SiC film tends to be substantially constant. The excessive supply of the silicon precursor may cause gas phase reaction on portions other than the surface of the wafer W and generation of powder residue. From this, it is clear that the ratio of the flow rate of the silicon precursor to the flow rate of the carbon precursor is preferably greater than or equal to 0.1 and smaller than or equal to 4.0. In order to suppress the generation of powder residue, it is effective to introduce an inert gas for diluting the silicon precursor or increase a gas flow velocity by decreasing a reaction pressure.

Referring back to FIG. 5, in step 5, an upper layer film is formed on the SiC film. The upper layer film is formed on the SiC film when it is necessary to suppress the release of BCMA-derived Cl atoms (halogen atoms) contained in the SiC film. Here, the upper layer film is a silicon (Si) film. In step 5, a temperature and a pressure in the reaction tube 11 are controlled to a set temperature T3 (e.g., 400° C.) and a set pressure P1 (e.g., 133.3 Pa (1 Torr)), respectively. The supply of disilane into the reaction tube 11 is continued, and the supply of BCMA into the reaction tube 11 is stopped. Accordingly, an amorphous Si film is formed as the upper layer film on the SiC film formed in step 4. However, it may not be necessary to form the upper layer film on the SiC film.

Next, in step 6, the temperature and the pressure in the reaction tube 11 are controlled to the set temperature T1 (e.g., 350° C.) or lower and the set pressure P1 or lower, and N₂ gas is supplied from the gas injector 13 to perform a purge process. Next, in step 7, the pressure in the reaction tube 11 is returned to the set pressure P3 (atmospheric pressure) and, then, the lid 16 of the reaction tube 11 is opened and the wafer boat 12 is lowered to be unloaded. The pressure in the reaction tube 11 is controlled by adjusting the opening degree of the pressure control valve 26 in a state where the gas exhaust unit 251 is in operation. For example, when the pressure in the reaction tube 11 is returned to the atmospheric pressure, N₂ gas is supplied into the reaction tube 11 and the pressure control valve 26 is fully closed to block between the reaction tube 11 and the gas exhaust unit 251. The temperature in the reaction tube 11 is controlled by adjusting the amount of power supplied to the heating unit 18.

Next, the cleaning of the reaction tube 11 for forming a SiC film will be described. After the wafer W having thereon the SiC film is unloaded from the wafer boat 12, an empty wafer boat 12 mounting no wafer W is loaded into the reaction tube 11 and the cleaning is performed. In the case of forming a SiC film using a carbon precursor having an unsaturated bond, C is polymerized and by-products tend to be adhered to a narrow portion or a low-temperature portion. Therefore, polymer by-products tend to be deposited to the vicinity of the pressure control valve 26 in the vacuum exhaust line which is narrow and has a temperature lower than that of the reaction tube 11.

In general, a halogen gas is used as a cleaning gas. Although the halogen gas can remove the Si component, it is difficult for the halogen gas to remove the C component. As will be described in the following test examples, the by-products generated by the cleaning are adhered to the vicinity of the pressure control valve 26. Accordingly, the pressure control valve 26 is not fully closed, which makes it difficult to control the pressure in the reaction tube 11.

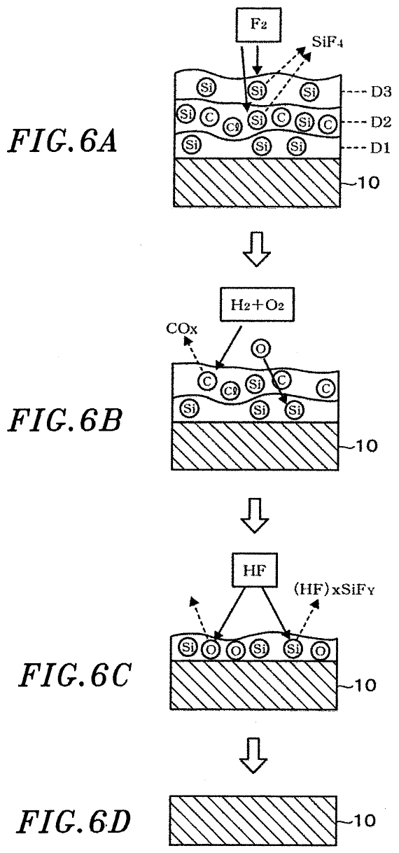

Therefore, in the cleaning method according to the embodiment of the present disclosure, the cleaning in which the first cleaning gas containing O₂ gas is supplied to the reaction tube 11 and the cleaning in which the second cleaning gas containing HF gas is supplied to the vacuum exhaust line 25 are performed. Further, in the present embodiment, cleaning using a halogen gas, e.g., F₂ gas, is performed before the supply of the first cleaning gas. Therefore, in this example, three-stage cleaning is performed using F₂ gas, the first cleaning gas, and the second cleaning gas. The respective cleaning processes will be described with reference to FIGS. 6A to 6D. FIGS. 6A to 6D schematically show the cleaning processes. FIG. 6A shows a state in which an amorphous Si film (D1), a SiC film (D), and an upper layer film (D3) are formed on the inner wall surface 10 of the reaction tube 11 or the vacuum exhaust line 25.

First, in the cleaning using F₂ gas, F₂ gas is supplied to the reaction tube 11 heated to, e.g., 350° C., through the gas injector 13 while the reaction tube 11 is exhausted by the gas exhaust unit 251 by opening the pressure control valve 26. F₂ gas flows through the reaction tube 11 toward the gas exhaust port 15 and is discharged through the vacuum exhaust line 25. In the case of supplying F₂ gas, as shown in FIG. 6A, F reacts with the Si component of the upper layer film (amorphous Si film) or the SiC film formed on the inner wall surface 10, thereby generating SiF₄. SiF₄ thus generated are scattered and removed.

Since the reaction tube 11 is heated to, e.g., 350° C., the separation of C from the SiC film by F₂ gas is facilitated by the heat, and a part of the C components in the reaction tube 11 is removed. The Si component and the C component peeled off from the reaction tube 11 flow through the vacuum exhaust line 25 together with the F₂ gas. At this time, the temperature of the vacuum exhaust line 25 is, e.g., 180° C., which is lower than that of the reaction tube 11, so that the scattered C components may be cooled and deposited as by-products.

Next, as shown in FIG. 6B, the first cleaning gas containing O₂ gas (in this example, O₂ gas and H₂ gas) is supplied. By adding H₂ gas, the reaction products between H₂ gas and O₂ gas improve an oxidizing power. In this process, these gases are supplied simultaneously from the gas injector 14 into the reaction tube 11 heated to, e.g., 350° C., while the reaction tube 11 is exhausted by the gas exhaust unit 251 by opening the pressure control valve 26. O₂ gas and H₂ gas flow through the reaction tube 11 toward the gas exhaust port 15 and are discharged through the vacuum exhaust line 25. When O₂ gas and H₂ gas are supplied into the reaction tube 11 heated to 350° C., a strong oxidizing power is obtained. Then, as shown in FIG. 6B, the C component of the SiC film, which is adhered to the inner wall of the reaction tube 11, is oxidized to CO₂ and scattered. Accordingly, the SiC film is removed. A part of Si of the amorphous Si film is oxidized by O₂ gas to form a silicon oxide film (SiO₂ film).

Thereafter, as shown in FIG. 6C, the second cleaning gas containing HF gas is supplied. Here, in order to prevent HF gas from inflicting damage on the main body of the reaction tube 11 made of quartz glass, the second cleaning gas is supplied only into the vacuum exhaust line 25. In other words, in this process, N₂ gas is supplied into the reaction tube 11 while the reaction tube 11 is exhausted by the gas exhaust unit 251 by opening the pressure control valve 26. Further, HF gas as the second cleaning gas is locally supplied to the vicinity of the upstream side of the pressure control valve 26 in the vacuum exhaust line 25. HF gas flows in the vacuum exhaust line 25 toward the gas exhaust unit 251 through the pressure control valve 26. Since HF gas has strong reactivity, carbon polymer by-products deposited in the vacuum exhaust line 25 or SiO₂ generated by the oxidation of the amorphous Si film are etched and removed.

On the other hand, N₂ gas supplied into the reaction tube 11 flows through the vacuum exhaust line 25 toward the gas exhaust unit 251. Therefore, the flow of HF gas into the reaction tube 11 made of quartz glass is prevented, and damages inflicted on the reaction tube 11 are suppressed. Since the temperature in the reaction tube 11 is 350° C., which is higher than that of the vacuum exhaust line 25, the amorphous Si film, the SiC film, the upper layer film, and the by-products adhered to the reaction tube 11 are removed by supplying F₂ gas and the first cleaning gas. Accordingly, it is not necessary to perform the cleaning using HF gas with respect to the reaction tube 11.

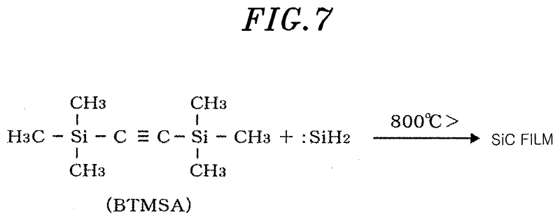

Next, another example of the carbon precursor will be described with reference to FIG. 7. The carbon precursor having an unsaturated carbon bond shown in FIG. 7 is bis(trimethylsilyl)acetylene (BTMSA) having a triple bond. A SiC film can be formed by thermally reacting BTMSA and the silicon precursor such as disilane at a temperature lower than 800° C., preferably 500° C. or lower. As shown in the following test examples, in the case of analyzing the chemical bonding state using XPS, Si—C bonds were detected. In the case of using BTMSA as the carbon precursor, it was possible to form a high-purity SiC film that did not contain halogen, a C—C bond, a C—H bond or the like.

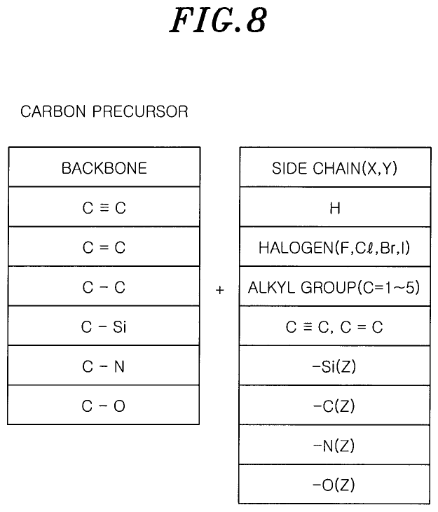

The carbon precursor that can be used for forming the SiC film is not limited to the above-described BCMA or BTMSA. Other carbon precursors may be used as long as the thermal reaction with the silicon precursor can proceed at a temperature lower than 800° C. to form a SiC film. As the carbon precursor, a combination of a backbone and a side chain shown in FIG. 8 can be used. The backbone is a triple bond portion in BCMA or BTMSA. The side chain is a portion bonded to the backbone. When the backbone is the triple bond, X represents a side chain bonded to one C and Y represents a side chain bonded to the other C. The side chains X and Y may be the same or different from each other.

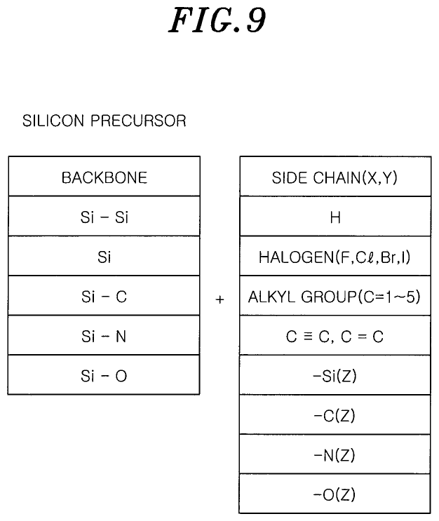

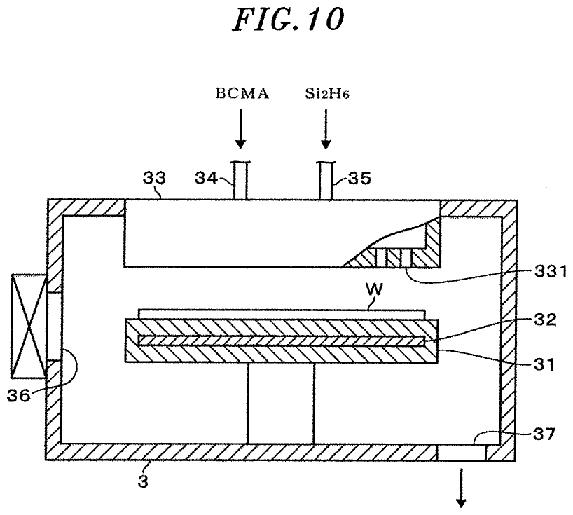

The backbone of the carbon precursor may have an unsaturated carbon bond of a C—C double bond or a C—C triple bond. Further, the backbone of the carbon precursor may have a single bond such as a C—C bond, a C—Si bond, a C—N bond, a C—O bond, or the like. This is because a SiC film may be formed by the mechanism of the aforementioned reaction model 2 when the single bond has a nucleophilic side chain. The side chain may have a hydrogen atom, halogen, C1-5 alkyl group, C—C triple bond, C—C double bond, Si(Z), C(Z), N(Z), O(Z), or the like. In the tables in FIGS. 8 and 9 showing variation of the side chains, Si(Z), C(Z), N(Z), and O(Z) indicate that the portion to be bonded to the backbone of C is Si, C, N, or O, and (Z) indicates any atomic group.

For the silicon precursor, combination of a backbone and a side chain shown in FIG. 9 can be used. In the case of disilane, the backbone is a Si—Si bond portion. The side chain is a portion bonded to the backbone. If the backbone is Si—Si, the side chain X bonded to one Si and the side chain Y bonded to the other Si may be the same or different. The backbone may be Si—Si, Si, Si—C, Si—N, Si—O, or the like. The side chain may have a hydrogen atom, halogen, C1-5 alkyl group, C—C triple bond, C—C double bond, Si(Z), C(Z), N(Z), O(Z), or the like. The silicon precursor that is thermally decomposed at a temperature lower than 800° C., e.g., 500° C. or lower, to generate SiH₂ radicals may be monosilane (SiH₄), trisilane (Si₃H₈), or the like, in addition to disilane.

In accordance with the above-described embodiment, the SiC film is formed by supplying the carbon precursor gas and the silicon precursor gas to the wafer W and performing the thermal reaction therebetween at a temperature lower than 800° C. The SiC film thus formed is of high quality and suitable as a hard mask material, an insulating film, and a low-k film in a multi-gate Fin-FET or the like. In the case of using a SiC film for a transistor of a semiconductor device, it is required to set a film forming temperature to be 500° C. or lower in order to suppress diffusion of metal from a metal wiring layer.

Even if the film formation can be performed at a temperature of 400° C. or lower, the technique for forming a SiC film using plasma may inflict great damage on the other films and wiring layers forming the semiconductor device due to the plasma. This is problematic. Therefore, the film forming method according to the embodiment of the present disclosure is effective to form a SiC film at a temperature lower than 800° C., preferably 500° C. or less, without using plasma, which also leads to the wide use of the SiC film.

Further, in the case of forming the upper layer film on the SiC film, even when the SiC film contains halogen atoms as in the case of a SiC film formed using a carbon precursor containing halogen atoms, the release of halogen atoms can be suppressed. Furthermore, the composition of the formed SiC film can be adjusted by selecting a carbon precursor such as BCMA or BTMSA, or by adjusting the ratio of the flow rate of the silicon precursor to the flow rate of the carbon precursor. Therefore, the SiC film having a film quality suitable for its intended use can be formed, which leads to the wide use of the SiC film.

In accordance with the cleaning method of the present disclosure, the SiC film adhered to the reaction tube 11 that is the processing chamber is removed by supplying the first cleaning gas containing O₂ gas. Further, by supplying the second cleaning gas containing HF gas to the vacuum exhaust line 25, polymer by-products and the like adhered to the vacuum exhaust line 25 are removed. Thus, only the vacuum exhaust line 25 can be cleaned using HF gas having strong reactivity, which makes it possible to clean the vacuum exhaust line 25 without damaging the reaction tube 11 made of quartz glass. Therefore, the by-products adhered to the pressure control valve 26 are removed. Accordingly, the opening and closing operation of the pressure control valve 26 is not disturbed by the by-products and the pressure control can be stably performed.

Next, another example of the film forming apparatus according to the embodiment of the present disclosure will be described with reference to FIG. 10. FIG. 10 shows an example of a single-wafer film forming apparatus including a vacuum container (processing chamber) 3 made of a metal. A mounting table 31 for mounting thereon a wafer W is disposed in a processing chamber 3, and a heating unit 32 is disposed in the mounting table 31. A gas shower head 33 is disposed above the mounting table 31 to be opposed to the mounting table 31. A plurality of gas injection holes 331 is formed in a bottom surface of the gas shower head 33. A carbon precursor supply unit 34 for supplying a carbon precursor gas and a silicon precursor supply unit 35 for supplying a silicon precursor gas are disposed on an upper surface of the gas shower head 33. The carbon precursor supply unit 34 includes a supply source or a supply path for a carbon precursor, e.g., BCMA, and the silicon precursor supply unit 35 includes a supply source or a supply path for a silicon precursor, e.g., disilane.

In FIG. 10, a reference numeral “36” denotes a transfer port for the wafer W and a reference numeral “37” denotes a gas exhaust port. As described in the above embodiment, the downstream side of the gas exhaust port 37 is connected to a gas exhaust unit through a vacuum exhaust line that is made of a metal and provided with a pressure control valve. In the example shown in FIG. 10, F₂ gas is used as the cleaning gas, and O₂ gas and H₂ gas are used as the first cleaning gas. The cleaning gases are supplied into the processing chamber 3 through the gas shower head 33. HF gas that is used as the second cleaning gas is supplied to the vicinity of the upstream side of the pressure control valve in the vacuum exhaust line (not shown). N₂ gas that is used as a purge gas is supplied into the processing chamber 3 through the gas shower head 33.

In the case of forming a SiC film using the film forming apparatus shown in FIG. 10, the wafer W is mounted on the mounting table 31 and the pressure in the processing chamber 3 is controlled to be within a range from, e.g., 399.9 Pa to 533.2 Pa (3 Torr to 4 Torr)). The heating unit 32 heats the wafer W on the mounting table 31 to a temperature lower than 800° C., e.g., within a range from 350° C. to 400° C., and BCMA and disilane are supplied concurrently from the gas shower head 33. Accordingly, BCMA and disilane thermally react to form a SiC film on the wafer W by CVD. Then, the supply of BCMA is stopped and only disilane is supplied to form a Si film as an upper layer film on the SiC film.

Further, in the film forming apparatus shown in FIG. 10, before the wafer W is loaded into the processing chamber 3, an amorphous silicon source gas, e.g., disilane, may be supplied to form an amorphous Si film on the inner wall surface of the processing chamber 3. After the above-described SiC film formation is performed in the processing chamber 3 and the wafer W having thereon the SiC film is unloaded from the processing chamber 3, the above-described three-stage cleaning is performed. In other words, after cleaning for removing the components of the upper layer film is performed by supplying F₂ gas, cleaning for oxidizing and removing the C components in the SiC film is performed using O₂ gas and H₂ gas (first cleaning gas). Next, cleaning of the vacuum exhaust line including the pressure control valve is performed by supplying HF gas (second cleaning gas) from the vicinity of the upstream side of the pressure control valve.

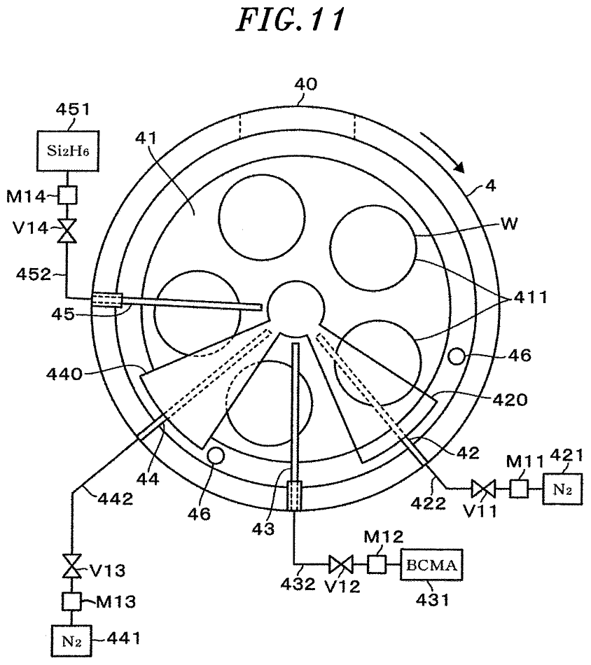

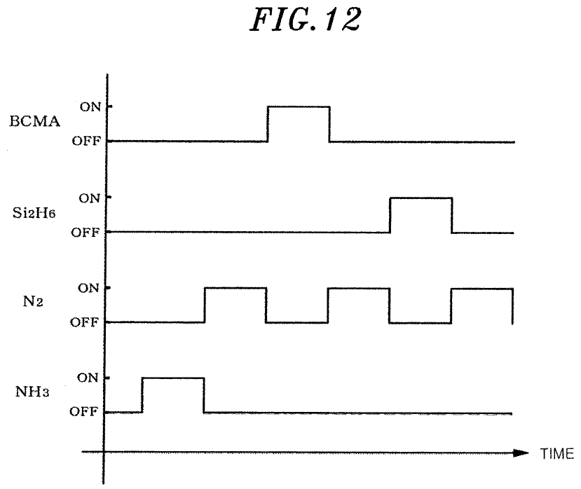

The SiC film may be formed by atomic layer deposition (ALD) in which a carbon precursor gas and a silicon precursor gas are alternately supplied to the wafer W to react with each other on the wafer W. The film forming apparatus shown in FIG. 11 is an example of an apparatus for forming a SiC film by alternately repeating a process of supplying a carbon precursor gas and a process of supplying a silicon precursor gas. The film forming apparatus includes the processing chamber 4 that is a vacuum container made of a metal and having a substantially circular planar shape, a rotation table 41 serving as a mounting table made of, e.g., quartz glass, and configured to mount thereon the wafer to rotate the wafer W.

The rotation table 41 is configured to be rotatable about the vertical axis with the center of the processing chamber 4 as the center of rotation. Recesses 411 each for mounting thereon the wafer W are formed at multiple, e.g., five, locations on the surface of the rotation table 41 along the circumferential direction thereof. A heating unit (not shown) is disposed in the space between the rotation table 41 and the bottom surface of the processing chamber 4 to heat the wafer W to a temperature lower than 800° C., e.g., within a range from 350° C. to 400° C. In FIG. 11, a reference numeral “40” denotes a transfer port for the wafer W.

Various nozzles are arranged at intervals in the circumferential direction of the processing chamber 4 in a region of the processing chamber 4 where the recesses 411 of the rotation table 41 pass. Specifically, the nozzles include a nozzle 42 for supplying a separation gas such as N₂ gas, a nozzle 43 for supplying a carbon precursor such as BCMA, a nozzle 44 for supplying a separation gas, and a nozzle 45 for supplying a silicon precursor such as disilane. These nozzles 42 to 45 are arranged in a clockwise direction from the transfer port 40 in that order and extend from the outer peripheral wall to the center of the processing chamber 4. A plurality of gas injection holes is formed in the bottom surface of each of the nozzles 42 to 45.

The base ends of the nozzles 42 to 45 are connected to gas supply sources 421, 431, 441, and 451 through supply lines 422, 432, 442, and 452, respectively. Valves V11 to V14 and flow rate controllers M11 to M14 are disposed in the supply lines 422, 432, 442, and 452, respectively. The carbon precursor supply unit in this example includes the gas supply source 431 and the supply line 432 for BCMA, and the silicon precursor supply unit includes the gas supply source 451 and the supply line 452 for disilane. Projected parts 420 and 440, each having a substantially fan-shaped planar shape, are formed above the two nozzles 42 and 44 for supplying separation gases, respectively. The separation gases (N₂ gas) discharged from the nozzles 42 and 44 spread from the respective nozzles 42 and 44 to both sides in the circumferential direction of the processing chamber 4 to separate the atmosphere where BCMA is supplied from the atmosphere where disilane is supplied.

On the outer peripheral side of the rotation table 41, gas exhaust ports 46 are disposed at the downstream side of the nozzle 43 for supplying BCMA and the downstream side of the nozzle 45 for supplying disilane such that the gas exhaust ports 46 are spaced apart from each other in the circumferential direction. Each of the gas exhaust ports 46 is connected to a gas exhaust mechanism (not shown) through a vacuum exhaust line (not shown) that is made of a metal and provided with a pressure control valve. In the example shown in FIG. 11, the illustration of the supply unit for supplying F₂ gas as a cleaning gas (in the case of coating the rotation table 41 made of quartz glass) is omitted. Further, the illustration of the supply unit for supplying O₂ gas and H₂ gas as the first cleaning gas and the supply unit for HF gas as the second cleaning gas is omitted. For example, F₂ gas, O₂ gas, and H₂ gas may join with any one of BCMA, disilane and the separation gases and, then, may be supplied into the processing chamber 4 through the corresponding one of the supply line 432, the supply line 452, and the supply lines 422 and 442. Further, HF gas is supplied to the vicinity of the upstream side of the pressure control valve in the vacuum exhaust line.

In the case of forming a SiC film using the film forming apparatus shown in FIG. 11, five wafers W, for example, are mounted on the rotation table 41 and the pressure in the processing chamber 4 is controlled to be within a range from, e.g., 399.9 Pa to 533.2 Pa (3 Torr to 4 Torr). Then, the rotation table 41 is rotated and the wafer W is heated to a temperature of 350° C. to 400° C. by the heating unit. Then, BCMA, disilane, and N₂ gas are supplied from the corresponding nozzles 42 to 45. As the rotation table 41 rotates, the wafer W alternately passes through a BCMA supply region and a disilane supply region. In the disilane supply region, it is required to generate SiH₂ radicals by thermally decomposing disilane. Therefore, the disilane supply region is wider than the BCMA supply region so that the thermal decomposition of disilane can proceed sufficiently.

In the BCMA supply region, BCMA gas is adsorbed on the surface of the wafer W. In the disilane supply region, the generated SiH₂ radicals react with BCMA on the surface of the wafer W to form a SiC film. By continuously rotating the rotation table 41, the process of supplying BCMA to the wafer W and the process of supplying disilane to the surface of the wafer W on which BCMA is adsorbed are alternately repeated. Accordingly, the thermal reaction of these precursors proceeds on the surface of the wafer W to form a SiC film. After the formation of the SiC film, the supply of BCMA is stopped and only disilane is supplied to form a Si film as an upper layer film on the SiC film.

In the film forming apparatus shown in FIG. 11, before the wafer W is loaded into the processing chamber 4, the amorphous Si film may be formed on the surface of the rotation table 41 by supplying an amorphous silicon source gas such as disilane. In this case, after the above-described SiC film forming process is performed in the processing chamber 4 and the wafer W having thereon the SiC film is unloaded from the processing chamber 4, the above-described three-stage cleaning is performed. In other words, cleaning is performed by supplying F₂ gas to the processing chamber 4, supplying the first cleaning gas to the processing chamber 4, and supplying the second cleaning gas to the vacuum exhaust line.

In the apparatus shown in FIG. 4 and the film forming apparatus shown in FIG. 10, the SiC film may be formed by the ALD method in which the carbon precursor gas and the silicon precursor gas are alternatively supplied. A film forming method in this case will be described with reference to FIG. 12. FIG. 12 is a time chart showing the timing of supplying a gas to the processing chamber. In this example, the apparatuses shown in FIGS. 4 and 10 are configured to supply ammonia (NH₃) gas as a pre-treatment gas into the processing chamber. For example, the apparatus shown in FIG. 4 is configured to supply NH₃ gas from one of the gas injectors 13 and 14. For example, the apparatus shown in FIG. 10 is configured to supply NH₃ gas from the gas shower head 33.

The pre-treatment facilitates the SiC film formation on the wafer W in a subsequent film forming process. As shown in FIG. 12, the pre-treatment is performed by supplying NH₃ gas into the processing chamber where the wafer W is loaded. Next, the supply of NH₃ gas to the processing chamber is stopped and N₂ gas is supplied to purge the inside of the processing chamber. Then, the carbon precursor, e.g., BCMA, is supplied in a state where the pressure in the processing chamber is set to be within a range from, e.g., 399.9 Pa to 533.2 Pa, and the temperature in the processing chamber is set to be lower than 800° C., e.g., within a range from 350° C. to 400° C. In this manner, BCMA is adsorbed on the surface of the wafer W.

Then, the supply of BCMA to the processing chamber is stopped and N₂ gas is supplied to purge the inside of the processing chamber. Next, the silicon precursor, e.g., disilane, is supplied in a state where the pressure in the processing chamber is set to be within a range from, e.g., 399.9 Pa to 533.2 Pa, and the temperature in the processing chamber is set to be lower than 800° C., e.g., within a range from 350° C. to 400° C. SiH₂ radicals generated by thermal decomposition of disilane react with BCMA on the surface of the wafer W to form SiC on the wafer W. Next, the supply of disilane to the processing chamber is stopped and N₂ gas is supplied to purge the inside of the processing chamber. By alternately repeating the supply of BCMA and the supply of disilane, the thermal reaction between the precursors proceeds on the surface of the wafer W. Accordingly, a SiC film is formed by the ALD method.

The SiC film formed by ALD in which the supply of BCMA to the wafer W and the supply of disilane to the wafer W are alternately repeated ensures the formation of a Si—C bond. Therefore, a high-quality and high-purity SiC film can be formed.

FIG. 12 shows an example in which the pre-treatment is performed before the formation of the SiC film. However, after the formation of the SiC film, post-treatment may be performed by supplying NH₃ gas or the like into the processing chamber where the wafer W is loaded. The post-treatment is performed to realize a low dielectric constant or the like.

In the present disclosure, the film forming apparatus may include a plasma generation unit to use plasma for a curing process, pre-treatment, post-treatment, and surface modification other than film formation. By irradiating the plasma, it is possible to improve the quality or the density of the SiC film. For example, in the apparatus shown in FIG. 4, a pair of electrodes may be disposed as the plasma generation unit between the wafer boat 12 and the gas injector 13 to generate the plasma of the gas. In the apparatus shown in FIG. 10, by connecting the high frequency power supply to the gas shower head 33 serving as the plasma generation unit, a parallel plate type plasma processing apparatus may be configured to generate the plasma between the mounting table 31 and the gas shower head 33.

In the above embodiments, it is not necessary to form an upper layer film on the SiC film. When the upper layer film is not formed, it is not necessary to perform the cleaning using a halogen gas. In the cleaning for removing the SiC film in the processing chamber, the SiC film is oxidized and the C component in the SiC film is removed. Therefore, the first cleaning gas contains O₂ gas and the first cleaning gas does not necessarily contain H₂ gas. For the first cleaning gas, O₂ gas, O₃ gas, a mixed gas of H₂ gas and O₂ gas, or O₂ plasma may be used. For the second cleaning gas containing HF gas, F₂ gas or ClF₃ gas may be used other than HF gas.

The embodiments of the present disclosure are illustrative in all respects and are not restrictive. The above-described embodiments can be embodied in various forms. Further, the above-described embodiments may be omitted, replaced, or changed in various forms without departing from the scope of the appended claims and the gist thereof.

### TEST EXAMPLES

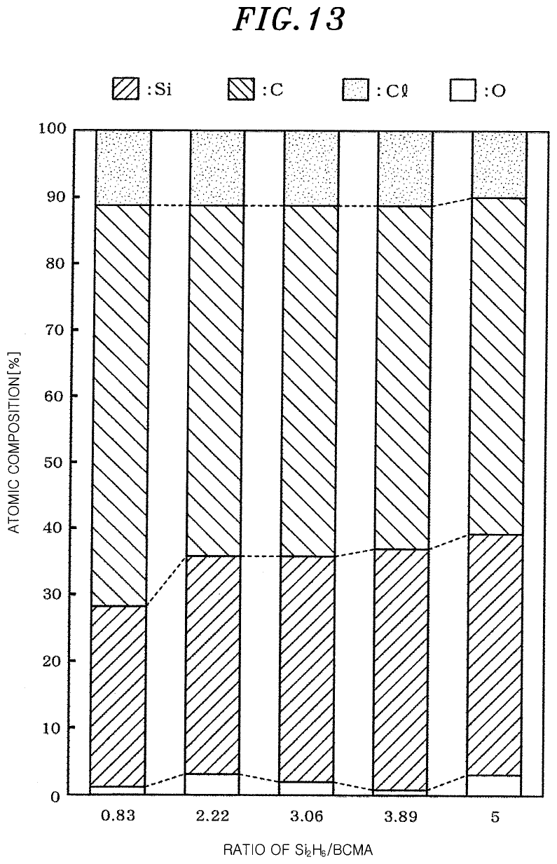

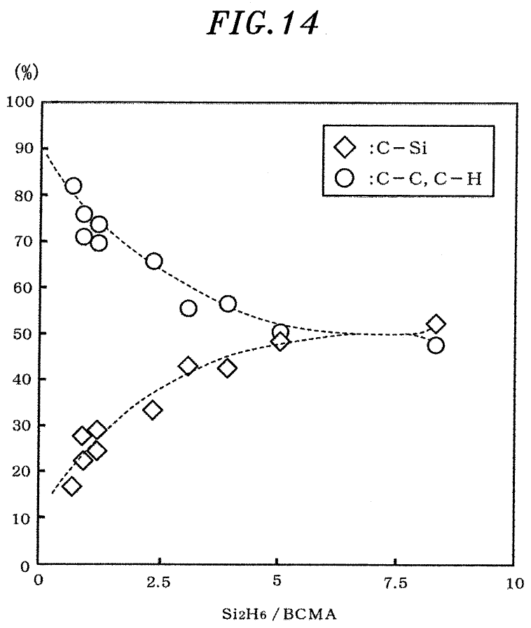

Next, an evaluation test for the SiC film forming method according to an embodiment of the present disclosure will be described. FIG. 13 shows XPS analysis results obtained in the case of forming a SiC film using BCMA as the carbon precursor and disilane as the silicon precursor while changing the ratio of the flow rate of disilane to the flow rate of BCMA. The SiC film was formed by the vertical heat treatment apparatus shown in FIG. 4 under the temperature conditions and the pressure conditions described in the time chart of FIG. 5 using the aforementioned technique. The results thereof are shown in FIGS. 13 and 14. In FIG. 13, the horizontal axis represents the ratio of the flow rate of disilane to the flow rate of BCMA (Si₂H₆/BCMA), and the vertical axis represents atomic composition.

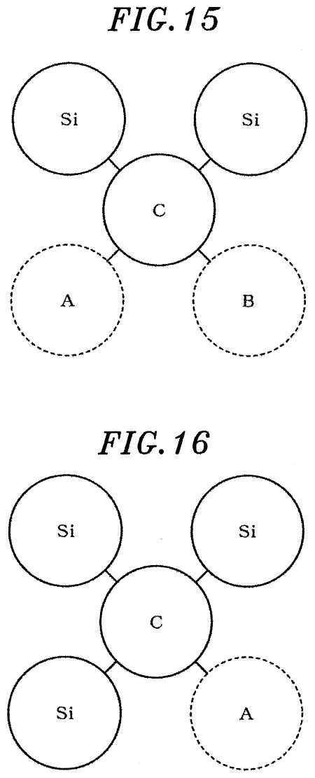

FIG. 14 is a characteristic diagram showing the composition ratio of a carbon bonding state. The horizontal axis in FIG. 14 represents the flow rate ratio (Si₂H₆/BCMA). In FIG. 14, a diamond-shaped (⋄) plot indicates a C—Si bond and a circular (◯) plot indicates a C—C bond and a C—H bond. As shown in FIG. 15, the C—C bond or the C—H bond indicates a state in which one or two Si atoms are bonded to C, and A and B bonded to C are C or H. As shown in FIG. 16, the C—Si bond indicates a state in which 3 to 4 Si atoms are bonded to C, and A bonded to C is C or H.

According to the results shown in FIG. 13, oxygen (O), silicon (Si), carbon (C), and chlorine (Cl) exist in the SiC film. From the atomic bonding state shown in FIG. 14, it was found that the Si—C bond was formed. Further, it was found that the atomic composition in the SiC film was changed by changing the flow rate ratio (Si₂H₆/BCMA). Specifically, as the flow rate of disilane in the flow rate ratio of Si₂H₆/BCMA was increased, Si in the SiC film was gradually increased from 27% to 37%, and C (C—Si bond) bonded to Si was increased from 15% to 52% and then saturated.

Further, according to the results shown in FIG. 14, when the flow rate ratio is within a range of 0 to about 5, the number of the C—Si bonds in the SiC film is increased as the flow rate of disilane is increased. When the flow rate ratio is 5 or more, the number of the C—Si bonds in the SiC film becomes substantially the same as the number of the C—C bonds or the number of the C—H bonds. Therefore, it is clear that when the flow rate ratio (Si₂H₆/BCMA) is within a range of 0 to about 5, the number of Si bonded to C contained in the SiC film can be changed by adjusting the flow rate ratio (Si₂H₆/BCMA) and, further, the SiC component amount can be adjusted.

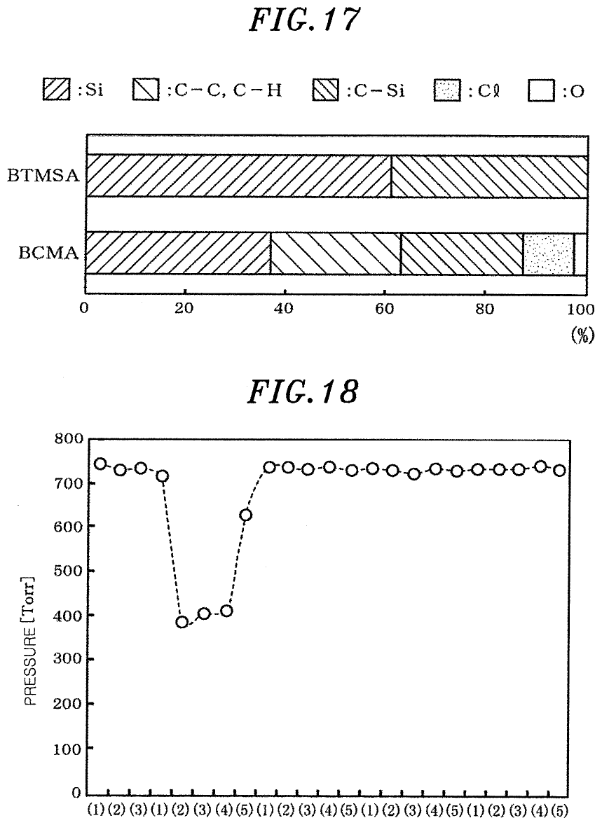

Next, in the vertical heat treatment apparatus shown in FIG. 4, a SiC film was formed using BCMA or BTMSA as a carbon precursor and disilane as a silicon precursor, and the change in the composition of the SiC film due to the difference in the carbon precursor was evaluated by performing XPS analysis on the formed SiC film. The SiC film was formed under the temperature conditions and the pressure conditions described in the time chart of FIG. 5 using the aforementioned technique. The result is shown in FIG. 17. In FIG. 17, C—C/C—H represents the bonding state of FIG. 15, and Si—C represents the bonding state of FIG. 16.

FIG. 17 shows that in the case of using, as a carbon precursor, BTMSA that does not contain a halogen group (Cl group) and does not have a nucleophilic side chain, the obtained atomic compositions were only Si and Si—C. Therefore, a SiC film having no impurities such as Cl, N, or the like could be formed. The formation of the Si—C bond demonstrates the mechanism of reaction model 1, in which SiH₂ radicals attack the π bond that is the triple bond during the formation of the SiC film. On the other hand, in the case of using BCMA, a SiC film containing Cl was formed. Since impurities may or may not exist in the SiC film depending on the uses of the SiC film, it is effective to control the mixing of impurities in the SiC film by selecting the carbon precursor.

Next, a cleaning evaluation test for the vertical heat treatment apparatus shown in FIG. 4 will be described. FIG. 18 shows processes performed on the reaction tube 11 or the vacuum exhaust line 25 and a pressure in the reaction tube 11 measured immediately after each of these processes. The processes shown in FIG. 18 include the following processes (1) to (5).

(1) Formation of an amorphous Si film on the inner wall of the reaction tube

(2) Formation of a SiC film on the wafer W

(3) Cleaning using F₂ gas

(4) Cleaning using the first cleaning gas (O₂ gas and H₂ gas)

(5) Cleaning of the vacuum exhaust line using the second cleaning (HF gas)

The processes (1) to (5) are performed under the above-described conditions. The process (1) is performed before the wafer W is loaded. After the amorphous Si film formation in the process (1) is performed, the pressure in the reaction tube 11 is returned to the atmospheric pressure and the wafer boat 12 mounting the wafer W is loaded into the reaction tube 11. Then, the process (2) is performed to form a SiC film on the wafer W. Next, the pressure in the reaction tube 11 is returned to the atmospheric pressure, and the wafer boat 12 mounting the wafer W having thereon the SiC film is unloaded from the reaction tube 11. Thereafter, the wafer boat 12 mounting no wafer W is loaded into the reaction tube 11 and the cleaning using F₂ gas in the process (3) is performed.

Immediately after the evaluation is started, the pressure in the reaction tube 11 is returned to the atmospheric pressure upon the completion of the process (3), and the amorphous Si film formation in the process (1) is performed again. Then, the processes (2) and (3) are performed consecutively and, in addition, the cleaning using H₂ gas and O₂ gas in the process (4) is performed. Next, the pressure in the reaction tube 11 is returned to the atmospheric pressure and, then, the cleaning for the vacuum exhaust line 25 using the second cleaning gas (HF gas) in the process (5) is performed. Then, the pressure in the reaction tube 11 is returned to the atmospheric pressure and the processes (1) to (5) are performed again.

In the processes (1) to (5), the pressure in the reaction tube 11 is returned to the atmospheric pressure after each process is completed, and the pressure in the reaction tube 11 is measured at that time. From the measurement result, it was found that when only the cleaning using F₂ gas (process (3)) was performed, the pressure in the reaction tube 11 was reduced to 400 Torr and it was not possible to return the pressure in the reaction tube 11 to the atmospheric pressure.

On the other hand, when the three-stage cleaning using F₂ gas (the process (3)), H₂ gas and O₂ gas (the process (4)), and HF gas (the process (5)) was performed, it was possible to return the pressure in the reaction tube 11 substantially to the atmospheric pressure. By performing the three-stage cleaning, the pressure in the reaction tube 11 was returned substantially to the atmospheric pressure even if the SiC film formation was repeated three times.

Therefore, it was found that the problem of the pressure control having difficulty to return the pressure in the reaction tube 11 to the atmospheric pressure can be solved by performing cleaning using HF gas. From this, it is clear that the by-products deposited in the vacuum exhaust line can be sufficiently removed by supplying HF gas, and the opening degree of the pressure control valve can be controlled without any problem. As a result, the pressure in the reaction tube 11 can be stably controlled.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made departing from the spirit of the disclosures. The accompanying claims and their equivalents are intended to cover such forms or modifications as would fall within the scope and spirit of the disclosures.

1. A film forming method comprising:
supplying a gas of a carbon precursor containing an organic compound having an unsaturated carbon bond to a substrate;
supplying a gas of a silicon precursor containing a silicon compound to the substrate; and
forming a carbon-silicon containing film on the substrate by thermally reacting the carbon precursor with the silicon precursor at a temperature lower than 800° C.

2. The film forming method of claim 1, wherein said supplying the gas of the carbon precursor and said supplying the gas of the silicon precursor are performed concurrently.

3. The film forming method of claim 1, wherein said forming the carbon-silicon containing film on a surface of the substrate is performed by alternately repeating said supplying the gas of the carbon precursor and said supplying the gas of the silicon precursor.

4. The film forming method of claim 1, wherein the organic compound has a nucleophilic side chain.

5. The film forming method of claim 4, wherein the nucleophilic side chain is a halogen atom.

6. The film forming method of claim 5, further comprising, after said forming the carbon-silicon containing film:
forming an upper layer film for suppressing a release of the halogen atom from the carbon-silicon containing film.

7. The film forming method of claim 6, wherein the upper layer film is a silicon film.

8. The film forming method of claim 1, wherein the organic compound is bis(chloromethyl)acetylene or bis(trimethylsily)acetylene.

9. The film forming method of claim 1, wherein the silicon compound generates radicals, each having an unpaired electron in a silicon atom, at a temperature of the thermal reaction.

10. The film forming method of claim 9, wherein the silicon compound is disilane.

11. The film forming method of claim 1, wherein a number of silicon bonded to carbon contained in the carbon-silicon containing film is changed by adjusting a ratio of a flow rate of the silicon precursor supplied in said supplying the gas of the silicon precursor to a flow rate of the carbon precursor supplied in said supplying the gas of the carbon precursor.

12. A method for cleaning a processing chamber where a substrate is accommodated and the film forming method described in claim 1 is performed, the processing chamber being made of quartz glass and connected to a metal vacuum exhaust line provided with a pressure control valve, the method comprising:
supplying an amorphous silicon source gas to the processing chamber before the substrate is loaded into the processing chamber to coat an inner wall surface of the processing chamber with an amorphous silicon film;
supplying a first cleaning gas containing an oxygen gas for removing the carbon-silicon containing film adhered to the inner wall surface of the processing chamber to the processing chamber after the film forming method is performed in the processing chamber having the inner wall surface coated with the amorphous silicon film and the substrate on which the carbon-silicon containing film is formed is unloaded; and
supplying a second cleaning gas containing a hydrogen fluoride gas to remove a silicon oxide film formed by oxidizing the amorphous silicon film using the oxygen gas contained in the first cleaning gas.

13. The method of claim 12, wherein in said supplying the second cleaning gas, the second cleaning gas is supplied into the vacuum exhaust line locally.

14. A film forming apparatus comprising:
a processing chamber in which a mounting table configured to mount thereon a substrate is disposed;
a carbon precursor supply unit configured to supply a gas of a carbon precursor containing an organic compound having an unsaturated carbon bond to the processing chamber;
a silicon precursor supply unit configured to supply a gas of a silicon precursor containing a silicon compound to the processing chamber; and
a heating unit configured to thermally react the carbon precursor and the silicon precursor supplied to the processing chamber at a temperature lower than 800° C. to thereby form a carbon-silicon containing film on the substrate.

15. The film forming apparatus of claim 14, wherein the processing chamber is made of quartz glass,
the film forming apparatus further comprising:
a metal vacuum exhaust line connected to the processing chamber and provided with a pressure control valve;
a silicon film source supply unit configured to supply an amorphous silicon source gas to the processing chamber to coat an inner wall surface of the processing chamber with an amorphous silicon film before the substrate is loaded into the processing chamber;
a first cleaning gas supply unit configured to supply a first cleaning gas containing an oxygen gas to the processing chamber to remove the carbon-silicon containing film adhered to the inner wall surface of the processing chamber; and
a second cleaning gas supply unit configured to supply a second cleaning gas containing a hydrogen fluoride gas to the vacuum exhaust line to remove a silicon oxide film formed by oxidizing the amorphous silicon film using the oxygen gas contained in the first cleaning gas.

16. The film forming apparatus of claim 15, wherein the second cleaning gas supply unit is connected to the vacuum exhaust line and supplies the second cleaning gas into the vacuum exhaust line locally.
